(19) United States
(12) Patent Application Publication
(10) Pub. No.: US 2015/0233982 A1
(43) Pub. Date: Aug. 20, 2015

(54) DETECTION OF LOAD-SHEDDING OF AN INVERTER

(71) Applicant: COMMISSARIAT A L'ENERGIE ATOMIQUE ET AUX ENERGIES ALTERNATIVES, Paris (FR)

(72) Inventor: Quoc-Tuan Tran, Gieres (FR)

(21) Appl. No.: 14/432,474

(22) PCT Filed: Oct. 1, 2013
(86) PCT No.: PCT/FR2013/052331

§ 371 Date: Mar. 30, 2015

(30) Foreign Application Priority Data
Oct. 1, 2012 (FR) 1259245

(51) Int. Cl. G01R 19/165; G01R 25/00; H02M 7/44; G01R 23/02

(52) U.S. Cl. CPC G01R 19/16538; G01R 23/02; G01R 25/00; H02M 7/44

(57) ABSTRACT

The invention relates to a method for detecting load-shedding of an inverter (22) connected to a power grid (3), comprising at least the steps of determining the time derivative of the voltage unbalance factor (RoCoVUF) between phases output by the inverter; determining the rate of change of frequency (RoCoF) of the voltage output by the inverter; multiplying (43) the two values; and comparing (46) same to a threshold (TH).

### CROSS-REFERENCE TO RELATED APPLICATIONS

The present application is a National Stage of PCT International Application Serial Number PCT/FR2013/052331, filed Oct. 1, 2013, which claims priority under 35 U.S.C. §119 of French Patent Application Serial Number 12/59245, filed Oct. 1, 2012, the disclosures of which are incorporated by reference herein.

### BACKGROUND OF THE INVENTION

1. Field of the Invention

The present invention generally relates to electricity supply network and, more particularly, to the load shedding of a decentralized production unit, connected to a power supply network.

2. Description of the Related Art

Electricity supply network more and more often comprise decentralized power generation units. Apart from conventional thermal, nuclear or hydraulic power plants, more and more low-power decentralized units (most often photovoltaic or wind-power units) are connected to the supply network. Typically, houses or industries are equipped with photovoltaic panels having their generated power reinjected, via an inverter, onto the electricity supply network. Such production units, called decentralized, are connected to the so-called low-voltage supply network which powers houses and small industries, that is, downstream of medium- or high-voltage-to-low voltage transformers. Such inverters or other devices connecting the unit to the supply network are then in parallel with the connection of the loads powered by the supply network.

The phase and voltage references of the inverters are provided by the supply network. Accordingly, if the supply network is to be disconnected from the inverter area, the inverter then is in a so-called load shedding situation, where it is isolated from the supply network. This may occur incidentally or intentionally, for example, during supply network maintenance operations. The inverter should then be stopped to avoid for the power that it generates to keep on being injected onto the supply network portion located downstream of the disconnection. Indeed, this is hazardous for the material, which is likely to be damaged, particularly when the supply network voltage is reinjected, and for the people performing the maintenance on the supply network portion that they believe to be disconnected.

One should thus be capable of detecting a load shedding situation in order to be able to switch off the inverter. Actually, the operating time of the isolated system should be decreased to a minimum to avoid powering a fault or to keep a faulty installation powered, to avoid powering the disconnected portion at an abnormal voltage or frequency, to enable automated resetting systems to operate properly, to protect the people close to the equipment, etc.

There are three categories of load shedding detection methods.

So-called communication methods require a direct communication between the supply network (more specifically a control unit of the supply network) and the decentralized unit. For example, a data transmission link enables the supply network to inform the decentralized unit of the load shedding situation. Such methods are very expensive and difficult to adapt to existing units, unless wireless communication means are provided, which further increases the cost.

So-called active methods comprise detecting an event intentionally placed on the supply network. For example, in a load-shedding situation, the supply network transmits disturbing pulses capable of being detected on the inverter side. Such methods require an action on the supply network side (to be able to generate disturbances). Further, incidental pulses may generate false detections.

So-called passive methods to which the present invention applies only use measurements made on the decentralized unit side. Current passive methods suffer from significant non-detection areas linked to the allowances which should be provided to avoid false triggerings.

### SUMMARY

An object of an embodiment of the present invention is to overcome all or part of the disadvantages of known load shedding detection techniques.

Another object of an embodiment of the present invention is to provide a passive solution.

Another object of an embodiment of the present invention is to provide a solution which does not disturb the supply network.

Another object of an embodiment of the present invention is to provide a solution which requires no additional equipment in existing inverters and which is easy to implant in the inverters.

To achieve all or part of these and other objects, an embodiment provides a method of detecting the load shedding of an inverter connected to an electricity supply network, comprising at least steps of:

determining the time derivative of the voltage unbalance factor between phases output by the inverter;

determining the time derivative of the frequency of the voltage output by the inverter;

multiplying the two values; and

comparing the result with a threshold.

According to an embodiment of the present invention, the method further comprises the steps of:

determining the time derivative of the reactive load of the inverter; and

taking into account this value in the multiplication step.

According to an embodiment of the present invention, the inverter delivers a three-phase voltage.

According to an embodiment of the present invention, the method further comprises a step of supplying a control signal to the inverter.

According to an embodiment of the present invention, the inverter is associated with photovoltaic panels.

A load shedding detection device capable of implementing the above method is also provided.

According to an embodiment of the present invention, the device comprises at least one voltage sensor connected to the output of the inverter.

According to an embodiment of the present invention, the device further comprises a reactive load sensor.

According to an embodiment of the present invention, the device further comprises means for calculating said derivatives.

The present invention also provides a solar power plant comprising:

at least one photovoltaic panel;

at least one inverter; and

a load shedding detection device.

### BRIEF DESCRIPTION OF THE DRAWINGS

The foregoing and other features and advantages will be discussed in detail in the following non-limiting description of specific embodiments in connection with the accompanying drawings, among which:

FIG. 1 is a very simplified partial representation of an electricity supply network to which the embodiments which will be described apply;

FIG. 2 illustrates the connection of a decentralized power generation device to a supply network;

FIG. 3 illustrates an embodiment of a load shedding detection device;

FIG. 4 illustrates another embodiment of a load shedding detection device; and

FIGS. 5A, 5B, 5C, 5D, 5E, 5F, 5G, and 5H are timing diagrams illustrating the operation of the embodiments of FIGS. 3 and 4.

### DETAILED DESCRIPTION

The same elements have been designated with the same reference numerals in the different drawings. For clarity, only those steps and elements which are useful to the understanding of the described embodiments have been shown and will be described. In particular, the decentralized production units and the inverters or the like devices have not been detailed, the described embodiments being compatible with current units and devices. Further, the structure of the supply network has not been detailed either, the embodiments being compatible with any usual three-phase supply network.

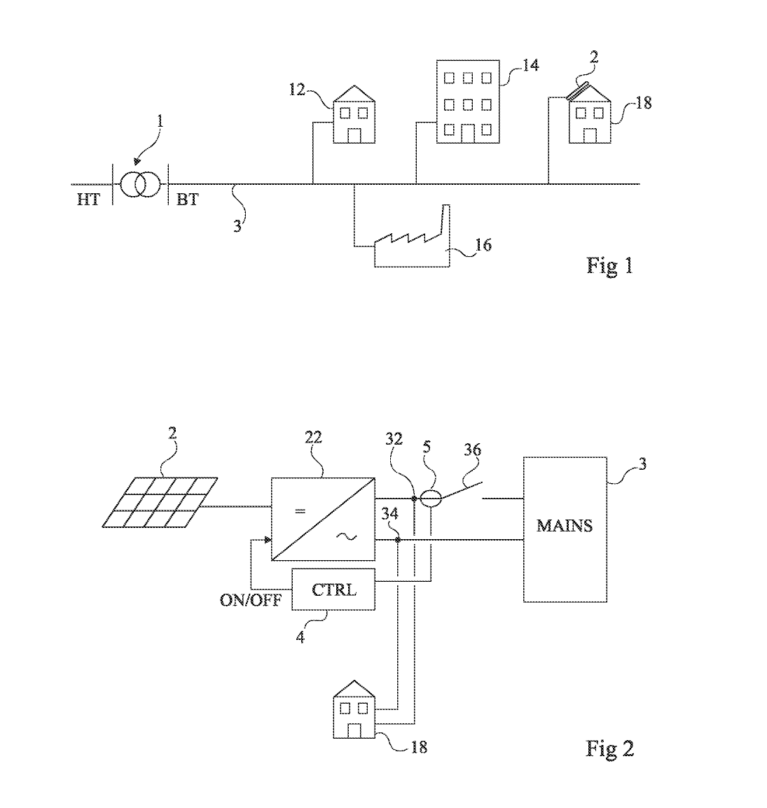

FIG. 1 very schematically shows in simplified fashion an example of an electricity supply network 3 downstream of a transformer 1 taking a high voltage HT (typically, several tens of kilovolts) down to a low voltage BT intended to power subscriber installations. The low voltage is for example 220 volts (between phase and neutral) or 380 volts (between phases). The various installations powered by the electric supply network may be individual houses 12, apartment buildings 14, workshops or industries 16. Other installations may be directly connected to the medium- or low-voltage supply network (heavy industry, rail transport, for example) but are then located upstream of transformer 1. Installations connected to a low-voltage supply network are here considered.

More and more often, installations (in the example of FIG. 1, a house 18) are equipped with power generation units (for example, solar or wind power units). These for example are photovoltaic panels 2 which are connected, via an inverter (not shown in FIG. 1) to the cables of supply network 3, and inject power onto the supply network.

FIG. 2 is a simplified representation of a system for connecting a decentralized production unit 2 to an electricity supply network 3 (MAINS). Typically, photovoltaic panels convert the solar energy that they receive into a DC current, which is processed by an inverter 22. The function of the inverter is to transform the DC current into an AC current capable of being injected onto the supply network. To achieve this, the inverter should receive information relative to the phase and to the voltage level of the AC signal from the supply network. Inverter 22 is in parallel on the supply network, that is, a load (for example, the equipment of house 18 supporting the solar panels) is connected to power supply terminals 32 and 34 common to supply network 3 and to the inverter. In the applications targeted by the embodiments which will be described, the inverter is three-phased. Load 18 may however be a three-phase or single-phase load.

In an incidental or intentional load shedding situation (symbolized in FIG. 2 by a switch 36 in the off state between terminal 32 and supply network 3), one should be able to stop (disable) inverter 22. If not, the electric devices connected downstream of switch 36 (or of the incidental cable break) remain powered by the inverter. This is dangerous for the people and adversely affects the equipment since the phase information is lost. This may for example raise an issue when the supply network is connected back. Further, this adversely affects the operation of the equipment detecting a loss of power and having a function of automatic resetting when the voltage reappears.

A load shedding detector 4 (CTRL) is thus provided to control a stopping of inverter 22 in the occurrence of a load shedding situation. In the case of a passive detector, measurements (sensor 5) of different variables at the output of inverter 22 are processed. Preferably, sensor(s) 5 are placed at closest to (the output of) inverter 22.

There is an increasing need to ascertain a fast load shedding of inverters associated with decentralized power generation units, as the number of small plants significantly increases, which considerably increases the number of possible sources of problems.

The embodiments which will be described concern passive methods, that is, methods which require neither an injection of disturbances onto the supply network in operation, nor a communication between the inverter and the supply network.

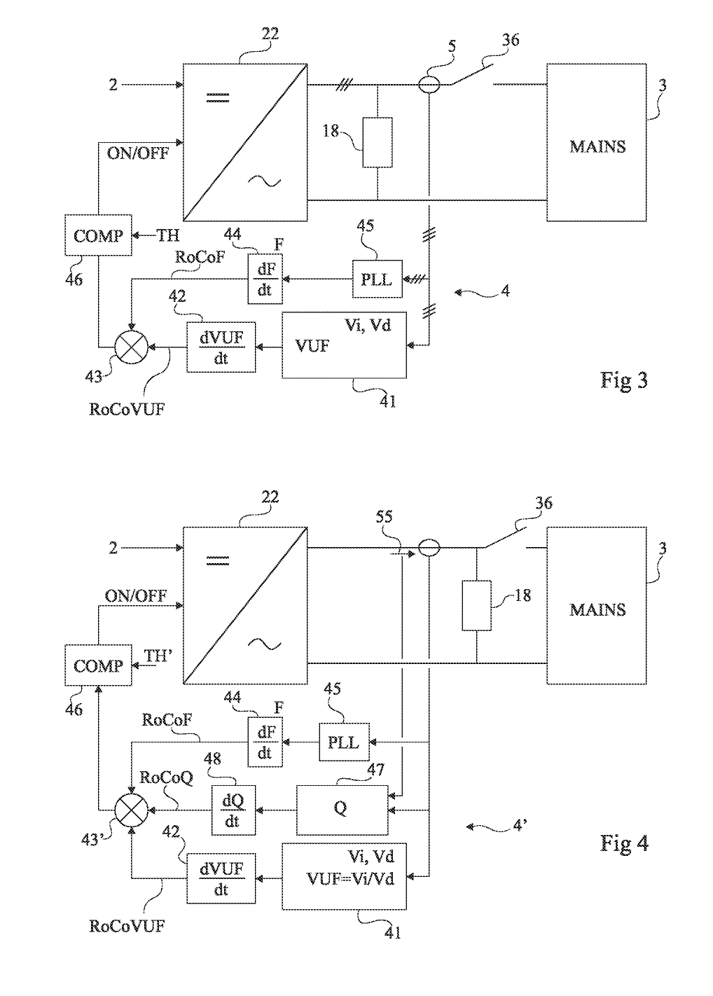

FIG. 3 very schematically shows in the form of blocks an embodiment of a load shedding detection device 4. This device uses measurements of the voltages present on the different phases of the three-phase voltage output by inverter 22. Sensor 5 thus provides three pieces of information.

It is provided to use the derivative of the voltage unbalance factor (RoCoVUF) of the inverter and to weight it with the derivative of the frequency (RoCoF—Rate of Change of Frequency).

The voltage unbalance factor, VUF, corresponds, in a three-phase supply network, to the ratio of inverse voltage Vi to forward voltage Vd. As a reminder, the forward voltage corresponds to the complex average of the three phases taken in the order (successively crossing zero) and the inverse voltage corresponds to the complex average of the three phases in a different order.

The calculation of value VUF is known and provides a value in percents corresponding to the following relation:

$$VUF = Vi / Vd , with$$

$$Vi = \frac{{V}_{ab} + a \cdot {V}_{bc} + {a}^{2} \cdot {V}_{ca}}{3} , and$$

$$Vd = \frac{{V}_{ab} + {a}^{2} \cdot {V}_{bc} + a \cdot {V}_{ca}}{3} ,$$

where

V_{ab}, V_{bc}, and V_{ca} designate the voltages between phases and

$$a = {e}^{j \frac{2 π}{3}}$$

represents the angle between phases.

Factor VUF, output by a block 41, is processed to obtain its time derivative. The derivative of factor VUF is thus calculated (block 42, dVUF/dt) to obtain value RoCoVUF. An indication of the fast voltage variations is then obtained.

The fact of monitoring the voltage unbalance factor (VUF) of inverter 22 enables to detect certain load shedding conditions. When supply network 3 is connected to inverter 22, the VUF has a low value (typically lower than 2%). However, in a load shedding situation, the impedance of load 18 is often higher than that of the supply network and the local load is seldom balanced, which increases the VUF. Indeed, when the inverter is connected to the supply network, statistically, the power consumption of the different phases is relatively balanced, which is very unlikely for a local load.

Value RoCoVUF is weighted (multiplied by a multiplier 43) by a value representing the time derivative of frequency RoCoF. Value RoCoF is obtained by calculating (block 44, dF/dt) the derivative of the voltage frequency. This derivative is obtained, for example, from a phase-locked loop (block 45, PLL). The information relative to the frequency derivative provides an indication of the fast frequency variations.

It could have been thought to combine the derivative of the frequency RoCoF with the derivative of the voltage (RoCoV—Rate of Change of Voltage). However, an advantage of using the derivative of the voltage unbalance factor between phases is that this value is independent from the actual values of the frequency and of the voltage. Thus, false detections are avoided in case of abrupt load or supply network production variations, which do not correspond to a load shedding situation.

The product of RoCoF by RoCoVUF provided by multiplier 43 is compared (block 46, COMP) with a threshold TH to output a signal enabling to turn on (ON) or to force the turning-off (OFF) of inverter 22.

FIG. 4 shows another embodiment according to which the derivative of the reactive power of the inverter is also taken into account. To achieve this, a measurement (sensor 55) of the current output by the inverter is used. This measurement is processed with the voltage to calculate the reactive power (block 47—Q) and the time derivative is deduced therefrom (block 48, dQ/dt). The time derivative of the reactive power RoCoQ (Rate of Change of Reactive Power Output) is thus obtained. This value is multiplied (multiplier 43′) by values RoCoF and RoCoVUF of the previous embodiment (FIG. 3). The result is compared with a threshold TH′ to disconnect the inverter if necessary.

Reactive power calculation techniques are known per se. There even exist direct reactive power sensors.

Using reactive power derivative provides a complement to the embodiment of FIG. 3. Indeed, this measurement is not sufficient per se, since the inverter can itself output a reactive power, which would generate a detection error.

Multiplying the different values enables to amplify variations in the presence of a real load shedding and to lessen a variation of a single one of the parameters which would result from another situation than load shedding. For example, in the case of a normal operation, the derivative of frequency RoCoF is almost zero. Thus, with a very high voltage unbalance factor or a strong reactive power variation, the product will remain close to 0.

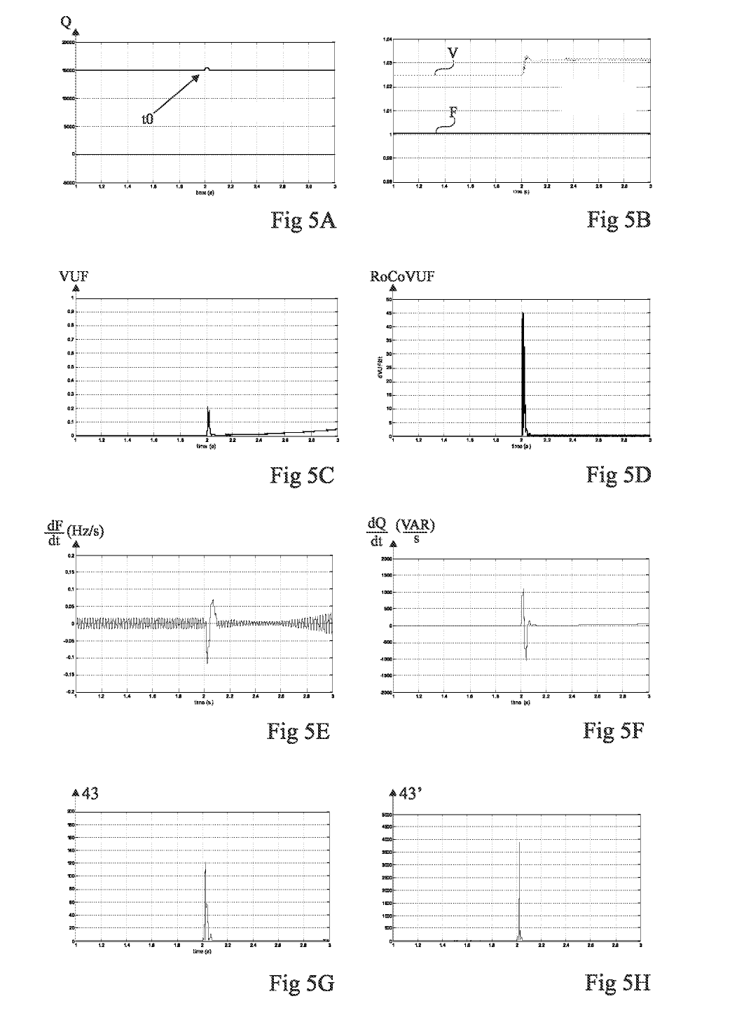

FIGS. 5A, 5B, 5C, 5D, 5E, 5F, 5G, and 5H are timing diagrams illustrating the operation of the embodiments of FIGS. 3 and 4.

FIG. 5A illustrates the variation of the reactive power of inverter 22. A load shedding time t0 at approximately 2 seconds on the time example taken in the drawings is assumed.

FIG. 5B illustrates, at a normalized scale, the variations of voltage V and of frequency F.

FIG. 5C illustrates the derivative of voltage unbalance factor VUF (in percents).

FIG. 5D illustrates derivative RoCoVUF of the voltage unbalance factor.

FIG. 5E illustrates derivative RoCoF of the frequency (in Hz/s).

FIG. 5F illustrates derivative RoCoQ of the reactive power (in VAR/s).

FIG. 5G illustrates the result provided by multiplier 43 of FIG. 3, that is, value RoCoVUF weighted with value RoCoF.

FIG. 5H illustrates the result provided by multiplier 43′ of FIG. 4, that is, the previous result weighted with value RoCoQ.

As illustrated in FIGS. 5G and 5H, the weighting causes a phenomenon of amplification of the effect of the load shedding detection, whereby, if one of these factors is close to 0, this means no load shedding and the product also remains close to 0.

In the above example, thresholds TH and TH′ may be set to values in the order of 100 and 3,000, respectively, and it can be seen that the provided results are almost zero before the load shedding, which demonstrates a reliability against false triggerings.

An advantage of the provided solutions is that, since they are passive, they introduce no disturbance into supply network 3.

Another advantage is that the efficiency of the detection is not affected if a plurality of inverters are connected in parallel (presence of a plurality of small plants connected to the supply network).

Another advantage is that the implementation of the described solutions does not require modifying the inverter. Existing installations can thus be easily adapted.

Various embodiments have been described. Various alterations, modifications, and improvements will readily occur to those skilled in the art. In particular, the practical implementation of the described embodiments is within the abilities of those skilled in the art based on the functional indications given hereabove and by using usual voltage variation, reactive load, and frequency measurement techniques. Further, the frequency at which the measurements are taken into account and at which the system reacts depends on the calculation power available in circuit 4. Further, although the invention has been more particularly described in relation with an example of a photovoltaic power plant, it more generally applies to any unit or system capable of being in a load shedding situation with respect to a three-phase supply network, for example, a battery associated with an inverter, a turbine, etc.

1. A method of detecting the load shedding of an inverter connected to an electricity mains, comprising at least steps of:
determining the time derivative of the voltage unbalance factor between phases output by the inverter;
determining the time derivative of the frequency of the voltage output by the inverter;
multiplying the two values of the time derivative of the voltage unbalance factor and the time derivative of the frequency to obtain a result; and
comparing the result with a threshold.

2. The method of claim 1, further comprising steps of:
determining the time derivative of the reactive load of the inverter; and
taking into account this value in the multiplication step.

3. The method of claim 1, wherein the inverter outputs a three-phase voltage.

4. The method of claim 1, further comprising a step of supplying a control signal to the inverter.

5. The method of claim 1, wherein the inverter is associated with photovoltaic panels.

6. A load shedding detection device, comprising:
means for determining a first value of the time derivative of the voltage unbalance factor between phases output by the inverter;
means for determining a second value of the time derivative of the frequency of the voltage output by the inverter;
means for multiplying the first and second values to obtain a result; and
means for comparing the result with a threshold.

7. The device of claim 6, comprising at least one voltage sensor connected to the output of the inverter.

8. The device of claim 6, further comprising a reactive load sensor.

9. The device of claim 6, comprising means for calculating said derivatives.

10. A solar power plant comprising:
at least one photovoltaic panel;
at least one inverter; and
the device comprising:
means for determining a first value of the time derivative of the voltage unbalance factor between phases output by the inverter;
means for determining a second value of the time derivative of the frequency of the voltage output by the inverter;
means for multiplying the first and second values to obtain a result; and
means for comparing the result with a threshold

11. The solar power plant of claim 10, comprising at least one voltage sensor connected to the output of the inverter.

12. The solar power plant of claim 10, further comprising a reactive load sensor.

13. The solar power plant of claim 10, comprising means for calculating said derivatives.

14. The method of claim 2, wherein the inverter outputs a three-phase voltage.

15. The method of claim 2, further comprising a step of supplying a control signal to the inverter.

16. The method of claim 3, further comprising a step of supplying a control signal to the inverter.

17. The method of claim 2, wherein the inverter is associated with photovoltaic panels.

18. The method of claim 3, wherein the inverter is associated with photovoltaic panels.

19. The method of claim 4, wherein the inverter is associated with photovoltaic panels.

20. The method of claim 14, wherein the inverter is associated with photovoltaic panels.
